(19) United States
(12) Patent Application Publication
(10) Pub. No.: US 2025/0227914 A1
(43) Pub. Date: Jul. 10, 2025

(54) SEMICONDUCTOR DEVICE AND METHOD OF FABRICATING THE SAME

(71) Applicant: SAMSUNG ELECTRONICS CO., LTD., SUWON-SI (KR)

(72) Inventors: Jaekyeong JEONG, Seoul (KR); Seunghee LEE, Suwon-si (KR); Jaeseok HUR, Seoul (KR); JIHYUN KHO, Suwon-si (KR); Yurim KIM, Suwon-si (KR); YONG-SUK TAK, Suwon-si (KR)

(73) Assignee: IUCF-HYU (Industry-University Cooperation Foundation Hanyang University), Seoul, (KR)

(21) Appl. No.: 18/939,637

(22) Filed: Nov. 7, 2024

(30) Foreign Application Priority Data
Jan. 10, 2024 (KR) 10-2024-0004485

(51) Int. Cl. H10B 12/00; H10B 51/20

(52) U.S. Cl. CPC H10B 12/315; H10B 12/05; H10B 12/30; H10B 51/20

(57) ABSTRACT

A semiconductor device may include a substrate, a bit line disposed on the substrate and extending along a first direction, a word line extending along a second direction perpendicular to the first direction, an oxide semiconductor structure disposed on a surface of the word line and extending along a third direction perpendicular to the first and second directions and a gate insulating pattern disposed between the word line and the oxide semiconductor structure. The oxide semiconductor structure includes a first oxide semiconductor pattern adjacent to the gate insulating pattern and a second oxide semiconductor pattern spaced apart from the gate insulating pattern, with the first oxide semiconductor pattern interposed therebetween. The first oxide semiconductor pattern comprises indium oxide, the second oxide semiconductor pattern comprises gallium oxide and a thickness of the first oxide semiconductor pattern is larger than a thickness of the second oxide semiconductor pattern.

### CROSS-REFERENCE TO RELATED APPLICATIONS

This U.S. non-provisional patent application claims priority under 35 U.S.C. § 119 to Korean Patent Application No. 10-2024-0004485, filed on Jan. 10, 2024, in the Korean Intellectual Property Office, the content of which is incorporated by reference herein in its entirety.

### 1. TECHNICAL FIELD

The present disclosure relates to semiconductors and, more specifically, to a semiconductor device and a method of fabricating the semiconductor device.

### 2. DISCUSSION OF THE RELATED ART

Semiconductor devices are becoming more important for their compact size, multifunctionality, and affordability, positioning them as vital components in the electronics industry. The semiconductor devices are classified into a semiconductor memory device for storing data, a semiconductor logic device for processing data, and a hybrid semiconductor device including both of memory and logic elements.

As the high-speed functionality and reduced power consumption in electronic devices becomes more important, semiconductor devices in electronic devices are also required to have high operating speeds and/or low operating voltages, and in order to satisfy this requirement, it is necessary to increase an integration density of the semiconductor device. However, as the integration density of the semiconductor device increases, the reliability and electrical characteristics of the semiconductor device may be deteriorated. Accordingly, many studies are being conducted to increase the reliability and electrical characteristics of the semiconductor device.

### SUMMARY

An embodiment of the inventive concept provides a semiconductor device with improved electrical and reliability characteristics, and a method of fabricating the same.

According to an embodiment of the inventive concept, a semiconductor device may include a substrate, a bit line disposed on the substrate and extending along a first direction, a word line extending along a second direction perpendicular to the first direction, an oxide semiconductor structure disposed on a surface of the word line and extending along a third direction perpendicular to the first and second directions and a gate insulating pattern disposed between the word line and the oxide semiconductor structure. Two of the first, second, and third directions are parallel to a top surface of the substrate, and the other is perpendicular to the top surface of the substrate. The oxide semiconductor structure includes a first oxide semiconductor pattern adjacent to the gate insulating pattern and a second oxide semiconductor pattern spaced apart from the gate insulating pattern, with the first oxide semiconductor pattern interposed therebetween. The first oxide semiconductor pattern comprises indium oxide, the second oxide semiconductor pattern comprises gallium oxide and a thickness of the first oxide semiconductor pattern is larger than a thickness of the second oxide semiconductor pattern.

According to an embodiment of the inventive concept, a semiconductor device may include a substrate, a bit line disposed on the substrate and extending along a first direction, a word line extending along a second direction perpendicular to the first direction, a channel structure disposed on a surface of the word line and extending along a third direction perpendicular to the first and second directions and a gate insulating pattern disposed between the word line and the channel structure. Two of the first, second, and third directions are parallel to the top surface of the substrate, and the remaining direction is perpendicular to the top surface of the substrate. The channel structure includes a first oxide semiconductor pattern in contact with the gate insulating pattern and a second oxide semiconductor pattern spaced apart from the gate insulating pattern, with the first oxide semiconductor pattern interposed therebetween. The first oxide semiconductor pattern comprises indium oxide, the second oxide semiconductor pattern comprises gallium oxide, and molar compositions of indium cations and gallium cations in the channel structure range from about 65% to about 75% and from about 25% to about 35%, respectively.

According to an embodiment of the inventive concept, a semiconductor device may include a substrate, a plurality of bit lines disposed on the substrate and extended in a first direction, a plurality of word lines extending along a second direction perpendicular to the first direction, oxide semiconductor structures disposed on a surface of the word line and extending along a third direction perpendicular to the first and second directions and a gate insulating pattern disposed between the word line and each of the oxide semiconductor structures. Two of the first, second, and third directions are parallel to a top surface of the substrate, and the remaining direction is perpendicular to the top surface of the substrate. Each of the oxide semiconductor structures includes a first oxide semiconductor pattern in contact with the gate insulating pattern and a second oxide semiconductor pattern spaced apart from the gate insulating pattern, with the first oxide semiconductor pattern interposed therebetween. The first oxide semiconductor pattern comprises indium oxide, the second oxide semiconductor pattern comprises gallium oxide, a thickness of the first oxide semiconductor pattern ranges from about 6 nm to about 7.425 nm, and a thickness of the second oxide semiconductor pattern ranges from about 1.275 nm to about 1.9 nm.

### BRIEF DESCRIPTION OF THE DRAWINGS

FIG. 1A is a schematic perspective view illustrating a semiconductor device according to an embodiment of the inventive concept.

FIG. 1B is a sectional view illustrating the semiconductor device of FIG. 1A.

FIG. 2A is a schematic perspective view illustrating a semiconductor device according to an embodiment of the inventive concept.

FIG. 2B is a sectional view illustrating the semiconductor device of FIG. 2A.

FIG. 3A is a schematic perspective view illustrating a semiconductor device according to an embodiment of the inventive concept.

FIG. 3B is a sectional view illustrating the semiconductor device of FIG. 3A.

FIG. 4 is a process flow chart illustrating a method of forming an oxide semiconductor structure, according to an embodiment of the inventive concept.

FIGS. 5A, 5B, 5C, 5D, 5E and 5F are cross-sectional views illustrating a process of fabricating a transistor including an oxide semiconductor structure, according to an embodiment of the inventive concept.

FIGS. 6A, 6B, 6C and 6D are cross-sectional views illustrating a process of fabricating a transistor including an oxide semiconductor structure, according to an embodiment of the inventive concept.

FIG. 7 is a graph showing a relationship between an overdrive voltage and a drain current, according to a first embodiment and first to fourth comparative examples.

FIG. 8 is a graph showing a relationship between a gate electrode and a field-effect mobility, according to the first embodiment and the first to fourth comparative examples.

### DETAILED DESCRIPTION

Example embodiments of the present inventive concepts will now be described more fully with reference to the accompanying drawings, in which example embodiments are shown.

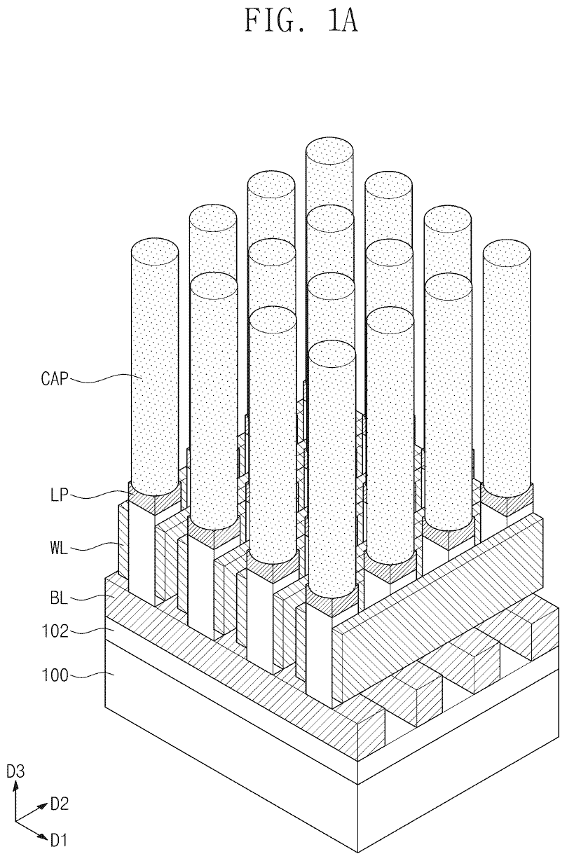

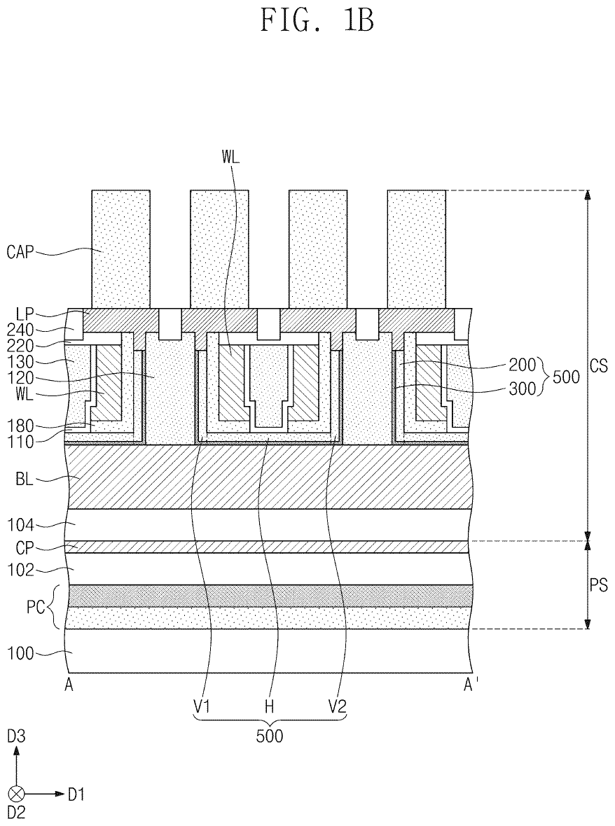

FIG. 1A is a schematic perspective view illustrating a semiconductor device according to an embodiment of the inventive concept. FIG. 1B is a sectional view illustrating the semiconductor device of FIG. 1A.

Referring to FIGS. 1A and 1B, the semiconductor device according to an embodiment of the inventive concept may include a substrate 100, a peripheral circuit structure PS disposed on the substrate 100, and a cell array structure CS disposed on the peripheral circuit structure PS.

The peripheral circuit structure PS may include a peripheral gate structure PC disposed on the substrate 100, a peripheral contact pad CP, and a first interlayer insulating layer 102 interposed therebetween. The peripheral gate structure PC may include a sense amplifier. The peripheral contact pad CP may be disposed on the peripheral gate structure PC. The first interlayer insulating layer 102 may be formed of or include at least one of silicon oxide (SiO₂), silicon nitride (Si₃N₄), silicon oxynitride, or low-k dielectric materials. As used herein, the term “low-k” may be understood to mean a material having a dielectric constant that is less than that of silicon oxide.

The cell array structure CS may include memory cells including vertical channel transistors. The cell array structure CS may include a plurality of bit lines BL, a second interlayer insulating layer 104, a plurality of oxide semiconductor structures 500, a plurality of word lines WL, a plurality of gate insulating patterns 180, and a capacitor CAP. The second interlayer insulating layer 104 may at least partially cover the peripheral contact pad CP. As used herein, the phrase “at least partially covering” may mean that the first element covers some or all of the second element.

In the present specification, a first direction D1 may be defined as an extension direction of the bit line BL. A second direction D2 may be perpendicular to the first direction D1 and may be defined as an extension direction of the word line WL. A third direction D3 may be defined as an extension direction of the oxide semiconductor structure 500. Here, two directions of the first, second, and third directions D1, D2, and D3 may be parallel to a top surface of the substrate 100, and the other may be perpendicular to the top surface of the substrate 100.

As shown in FIGS. 1A and 1B, the bit line BL may be extended in a direction, which is parallel to the top surface of the substrate 100, and the first direction D1 may be parallel to the top surface of the substrate 100. The word line WL may be extended in a direction, which is parallel to the top surface of the substrate 100 and is perpendicular to the extension direction of the bit line BL, and the second direction D2 may be parallel to the top surface of the substrate 100 and may be perpendicular to the first direction D1. The third direction D3 may be perpendicular to the top surface of the substrate 100.

The bit line BL may be provided on the substrate 100. In an embodiment of the present inventive concept, a plurality of bit lines BL may be spaced apart from each other along the second direction D2. The bit line BL may be electrically connected to the peripheral gate structure PC through a contact plug and the peripheral contact pad CP.

The bit line BL may be formed of or include at least one of, for example, doped polysilicon, metallic materials (e.g., Aluminum (Al), Copper (Cu), Titanium (Ti), Tantalum (Ta), Ruthenium (Ru), Tungsten (W), Molybdenum (Mo), Platinum (Pt), Nickel (Ni), and Cobalt (Co)), conductive metal nitride materials (e.g., Titanium Nitride (TiN), Tantalum Nitride (TaN), Tungsten Nitride (WN), Niobium Nitride (NbN), Titanium Aluminum Nitride (TiAlN), Titanium Silicon Nitride (TiSiN), Tantalum Silicon Nitride (TaSiN), and Ruthenium Titanium Nitride (RuTiN)), conductive metal silicide materials or conductive metal oxide materials (e.g., Platinum Oxide (PtO), Ruthenium Dioxide (RuO₂), Iridium Dioxide (IrO₂), Strontium Ruthenate (SrRuO₃) (SRO), (Ba,Sr) Barium strontium Ruthenate (RuO₃) (BSRO), Calcium Ruthenate (CaRuO₃) (CRO), and Lanthanum Strontium Cobaltate (LSCo)).

The oxide semiconductor structure 500 may be disposed on the bit line BL. For example, a bottom surface of the oxide semiconductor structure 500 may be in contact with a top surface of the bit line BL. In the present specification, the oxide semiconductor structure may be a channel structure. In an embodiment of the present inventive concept, a plurality of oxide semiconductor structures 500 may be provided. The oxide semiconductor structures 500 may be spaced apart from each other along the first and second directions D1 and D2.

The oxide semiconductor structure 500 may include a first vertical portion V1 and a second vertical portion V2, which are provided to face each other, and a horizontal portion H, which connects the first and second vertical portions V1 and V2 to each other. The first and second vertical portions V1 and V2 may extend along the third direction D3. According to an embodiment of the present inventive concept, the oxide semiconductor structure 500 might not include the horizontal portion H.

The horizontal portion H of the oxide semiconductor structure 500 may include a common source/drain region, and upper portions of the first and second vertical portions V1 and V2 may include first and second source/drain regions, respectively. The first vertical portion V1 may include a first channel region between the common source/drain region and the first source/drain region, and the second vertical portion V2 may include a second channel region between the common source/drain region and the second source/drain region. Each of the first and second vertical portions V1 and V2 may be electrically connected to the bit line BL. For example, the semiconductor device be a pair of vertical channel transistors sharing one bit line BL.

The oxide semiconductor structure 500 may include a first oxide semiconductor pattern 200 and a second oxide semiconductor pattern 300. There may be a visible boundary between the first and second oxide semiconductor patterns 200 and 300. The second oxide semiconductor pattern 300 may be in contact with the bit line BL. For example, a part of the second oxide semiconductor pattern 300 may extend towards the bit line BL and be in contact with a top surface of the bit line BL. The oxide semiconductor structure 500 may include one first oxide semiconductor pattern 200 and one second oxide semiconductor pattern 300.

The first oxide semiconductor pattern 200 may be formed of or include indium oxide (In₂O₃). The second oxide semiconductor pattern 300 may be formed of or include gallium oxide (Ga₂O₃). A molar composition of indium cations in the oxide semiconductor structure 500 may range from about 65% to 75%. A molar composition of gallium cations in the oxide semiconductor structure 500 may range from about 25% to 35%. In an embodiment of the present inventive concept, the first oxide semiconductor pattern 200 may be formed of or include In₂O₃. The second oxide semiconductor pattern 300 may be formed of or include Ga₂O₃.

The word line WL may be disposed between the first and second vertical portions V1 and V2. For example, the oxide semiconductor structure 500 may be disposed on a surface of the word line WL. In an embodiment of the present inventive concept, a plurality of word lines WL may be provided. The word lines WL may be spaced apart from each other along the first direction D1.

The word lines WL, which are disposed on the oxide semiconductor structure 500, may face each other along the first direction D1. Here, one of the word lines WL may be disposed adjacent to the first channel region of the first vertical portion V1 and may control the first channel region. Another one of the word lines WL may be disposed to at least partially cover an inner side surface of the second vertical portion V2, and the inner side surface of the second vertical portion V2 may be a side surface of the second vertical portion V2 facing the first vertical portion V1. Another one of the word lines WL may be disposed adjacent to the second channel region of the second vertical portion V2 and may control the second channel region.

The word line WL may be formed of or include at least one of, for example, doped polysilicon, metallic materials (e.g., Al, Cu, Ti, Ta, Ru, W, Mo, Pt, Ni, and Co), conductive metal nitride materials (e.g., TiN, TaN, WN, NbN, TiAlN, TiSiN, TaSiN, and RuTiN), conductive metal silicide materials or conductive metal oxide materials (e.g., PtO, RuO₂, IrO₂, SrRuO₃ (SRO), (Ba,Sr) RuO₃ (BSRO), CaRuO₃ (CRO), and LSCo).

The gate insulating pattern 180 may be interposed between the oxide semiconductor structure 500 and the word line WL. For example, the gate insulating pattern 180 may be interposed between the inner side surface of the first vertical portion V1 and one of the word lines WL, between the inner side surface of the second vertical portion V2 and another one of the word lines WL, between the horizontal portion H and a bottom surface of one of the word lines WL, and between the horizontal portion H and a bottom surface of another one of the word lines WL. The word line WL may be spaced apart from the oxide semiconductor structure 500 by the gate insulating pattern 180. The gate insulating pattern 180 may at least partially cover the oxide semiconductor structure 500. The gate insulating pattern 180 may be formed of or include at least one of silicon oxide (SiO₂), silicon oxynitride (Si₃N₄), or high-k dielectric materials whose dielectric constants are higher than that of silicon oxide.

Here, the first oxide semiconductor pattern 200 may be disposed closer to the gate insulating pattern 180 than the second oxide semiconductor pattern 300. For example, the first oxide semiconductor pattern 200 may be in contact with the gate insulating pattern 180. The first oxide semiconductor pattern 200 may be interposed between the gate insulating pattern 180 and the second oxide semiconductor pattern 300. For example, the second oxide semiconductor pattern 300 may be spaced apart from the gate insulating pattern 180 by the first oxide semiconductor pattern 200. A thickness of the first oxide semiconductor pattern 200 may be larger than a thickness of the second oxide semiconductor pattern 300. In an embodiment of the present inventive concept, the thickness of the first oxide semiconductor pattern 200 may range from about 6 nm to 7.425 nm. The thickness of the second oxide semiconductor pattern 300 may range from about 1.275 nm to 1.9 nm. According to an embodiment of the present inventive concept, the thickness of the first oxide semiconductor pattern 200 may range from about 3 nm to 7 nm, and the thickness of the second oxide semiconductor pattern 300 may range from about 1 nm to 2 nm.

A first insulating pattern 120 may be interposed between the oxide semiconductor structures 500, which are adjacent to each other along the first direction D1. The first insulating patterns 120 may extend along the second direction D2 and cross the bit line BL and may be spaced apart from each other along the first direction D1. The first insulating pattern 120 may cover at least a portion of outer side surfaces of the first and second vertical portions V1 and V2. In an embodiment of the present inventive concept, the first insulating pattern 120 may be formed of or include at least one of silicon oxide (SiO₂), silicon nitride (Si₃N₄), silicon oxynitride, or low-k dielectric materials.

A second insulating pattern 130 may be disposed between the word lines WL, which are disposed in the oxide semiconductor structure 500. In an embodiment of the present inventive concept, a plurality of second insulating patterns 130 may be provided. The second insulating patterns 130 may extend along the second direction D2 and cross the bit line BL and may be spaced apart from each other along the first direction D1. In an embodiment of the present inventive concept, the second insulating pattern 130 may be formed of or include at least one of silicon oxide (SiO₂), silicon nitride (Si₃N₄), silicon oxynitride, or low-k dielectric materials.

A protection pattern 110 may be interposed between the word line WL and the second insulating pattern 130. The protection pattern 110 may at least partially cover an inner side surface of the word line WL. The protection pattern 110 may be formed of or include at least one of silicon oxide (SiO₂), silicon nitride (Si₃N₄), or silicon oxynitride.

A capping pattern 220 may be provided on a top surface of the word line WL. The capping pattern 220 may at least partially cover top surfaces of the protection pattern 110 and the second insulating pattern 130. In an embodiment of the present inventive concept, the capping pattern 220 may be formed of or include at least one of silicon oxide (SiO₂), silicon nitride (Si₃N₄), or silicon oxynitride.

Landing pads LP may be provided on the first and second vertical portions V1 and V2 of the oxide semiconductor structure 500, respectively. The landing pads LP may be in direct contact with and may be electrically connected to the first and second vertical portions V1 and V2. When viewed in a plan view, the landing pads LP may be spaced apart from each other along the first and second directions D1 and D2 and may be arranged in various shapes (e.g., matrix, zigzag, and honeycomb shapes). When viewed in a plan view, each of the landing pads LP may have various shapes (e.g., circular, elliptical, rectangular, square, diamond, and hexagonal shapes).

In an embodiment, the landing pads LP may be formed of at least one of doped polysilicon, The chemical formulas listed include Aluminum (Al), Copper (Cu), Titanium (Ti), Tantalum (Ta), Ruthenium (Ru), Tungsten (W), Molybdenum (Mo), Platinum (Pt), Nickel (Ni), Cobalt (Co), Titanium Nitride (TiN), Tantalum Nitride (TaN), Tungsten Nitride (WN), Niobium Nitride (NbN), Titanium Aluminum (TiAl), Titanium Aluminum Nitride (TiAIN), Titanium Silicon (TiSi), Titanium Silicon Nitride (TiSiN), Tantalum Silicon (TaSi), Tantalum Silicon Nitride (TaSiN), Ruthenium Titanium Nitride (RuTiN), Nickel Silicon (NiSi), Cobalt Silicon (CoSi), Iridium Oxide (IrOx), and Ruthenium Oxide (RuOx), or combinations thereof, but the inventive concept is not necessarily limited to this example.

A third interlayer insulating layer 240 may be provided on the first and second insulating patterns 120 and 130 and fill a space between the landing pads LP. For example, the third interlayer insulating layer 240 may at least partially cover side surfaces of the landing pads LP. The third interlayer insulating layer 240 may be formed of or include at least one of silicon oxide (SiO₂), silicon nitride (Si₃N₄), or silicon oxynitride and may have a single- or multi-layered structure.

The capacitor CAP may be provided on each of the landing pads LP. The capacitor CAP may be electrically and respectively connected to the first and second vertical portions V1 and V2 of the oxide semiconductor structure 500 through the landing pads LP. The capacitor CAP may include a first electrode, a second electrode, and a dielectric layer interposed therebetween.

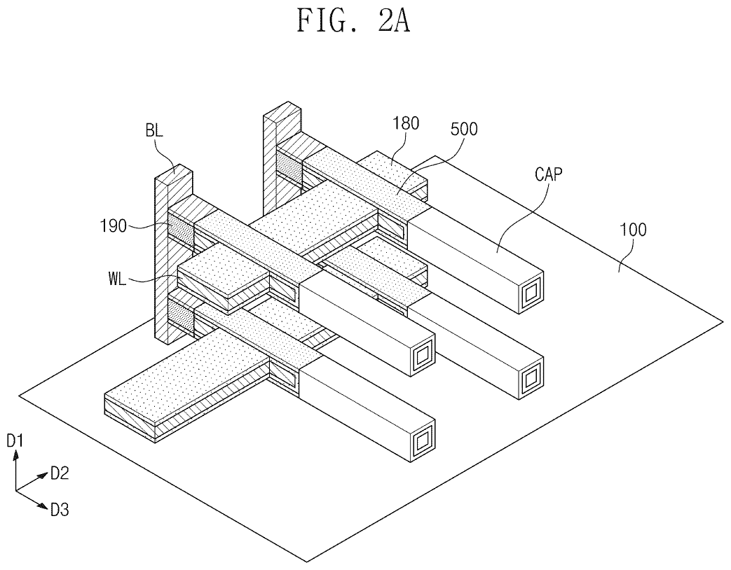

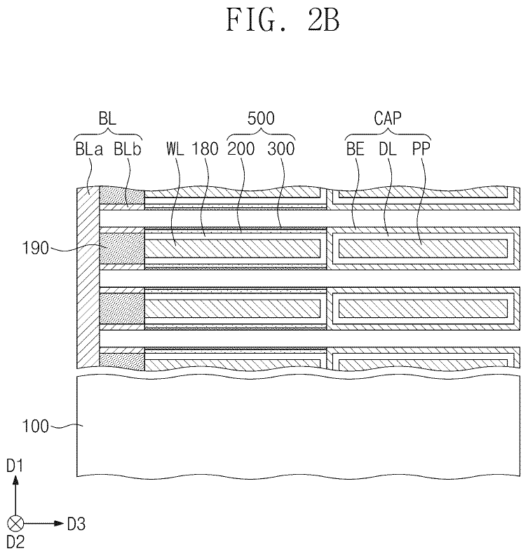

FIG. 2A is a schematic perspective view illustrating a semiconductor device according to an embodiment of the present inventive concept. FIG. 2B is a sectional view illustrating the semiconductor device of FIG. 2A.

Referring to FIGS. 2A and 2B, the semiconductor device may include the bit line BL, the word line WL, the capacitor CAP, the oxide semiconductor structure 500, and the gate insulating pattern 180, which are provided on the substrate 100.

As shown in FIGS. 2A and 2B, the bit line BL may extend along a direction perpendicular to the top surface of the substrate 100, which is the first direction D1 perpendicular to the top surface of the substrate 100. The word line WL may extend along a direction parallel to the top surface of the substrate 100, which is the second direction D2 parallel to the top surface of the substrate 100. The oxide semiconductor structure 500 may be extend along a direction, which is parallel to the top surface of the substrate 100 and is perpendicular to the extension direction of the word line WL, which is the third direction D3 parallel to the top surface of the substrate 100 and perpendicular to the second direction D2.

In an embodiment of the present inventive concept, a plurality of bit lines BL may be provided, and each of the bit lines BL may include a vertical bit line portion BLa, which extends along the first direction D1, and a plurality of horizontal bit line portions BLb, which are connected to the vertical bit line portion BLa and extend along the third direction D3. Here, a third insulating pattern 190 may be interposed between the horizontal bit line portions BLb. In some embodiments, the horizontal bit line portion BLb may be omitted, unlike the illustrated structure.

The word lines WL may extend along the second and third directions D2 and D3. A side surface of the word line WL may be in contact with the third insulating pattern 190. For example, the side surface of the word line WL may be in contact with a side surface of the third insulating pattern 190.

The gate insulating pattern 180 may at least partially cover a top surface, a bottom surface, and a side surface of each of the word line WL. Here, the gate insulating pattern 180 might not cover a side surface of the word line WL, which is in contact with the third insulating pattern 190.

The oxide semiconductor structure 500 may be disposed on bottom and top surfaces of the word line WL and may extend along the third direction D3. A side surface of the oxide semiconductor structure 500 may be connected to the bit line BL. The gate insulating pattern 180 may be disposed between the oxide semiconductor structure 500 and the word line WL.

The oxide semiconductor structure 500 may include the first oxide semiconductor pattern 200 and the second oxide semiconductor pattern 300. The first oxide semiconductor pattern 200 may be formed of or include indium oxide (In₂O₃). The second oxide semiconductor pattern 300 may be formed of or include gallium oxide (Ga₂O₃). The thickness of the first oxide semiconductor pattern 200 may be larger than the thickness of the second oxide semiconductor pattern 300. In an embodiment of the present inventive concept, the thickness of the first oxide semiconductor pattern 200 may range from about 6 nm to 7.425 nm. The thickness of the second oxide semiconductor pattern 300 may range from about 1.275 nm to 1.9 nm. According to an embodiment of the present inventive concept, the thickness of the first oxide semiconductor pattern 200 may range from about 3 nm to 7 nm, and the thickness of the second oxide semiconductor pattern 300 may range from about 1 nm to 2 nm.

The first oxide semiconductor pattern 200 may be disposed closer to the gate insulating pattern 180 than the second oxide semiconductor pattern 300. For example, the first oxide semiconductor pattern 200 may be in contact with top and bottom surfaces of the gate insulating pattern 180, and the first oxide semiconductor pattern 200 may be interposed between the gate insulating pattern 180 and the second oxide semiconductor pattern 300. The second oxide semiconductor pattern 300 may be spaced apart from the gate insulating pattern 180 by the first oxide semiconductor pattern 200. The word line WL and one oxide semiconductor structure 500 may constitute a memory transistor.

Each of the capacitors CAP may be connected to a surface of the corresponding oxide semiconductor structure 500 and a surface of the gate insulating pattern 180. The capacitors CAP may extend along the third direction D3 and may be arranged along the second direction D2.

Each of the capacitor CAP may include a first electrode BE, a dielectric layer DL, and a second electrode PP. For example, the first electrode BE may be in contact with a side surface of the oxide semiconductor structure 500 and a side surface of the gate insulating pattern 180. The dielectric layer DL may be interposed between the first electrode BE and the second electrode PP. The first and second electrodes BE and PP may be formed of or include at least one of metallic materials (e.g., tungsten (W), aluminum (Al), titanium (Ti), tantalum (Ta), and ruthenium (Ru)). The dielectric layer DL may be formed of or include at least one of silicon oxide (SiO₂) or metal oxide materials and may have a single-or multi-layered structure. The metal oxide materials may include aluminum oxide (Al₂O₃), hafnium oxide (HfO₂), and zirconium oxide (ZrO₂). The memory transistor and the capacitor CAP, which is connected to the oxide semiconductor structure 500, may constitute one memory cell.

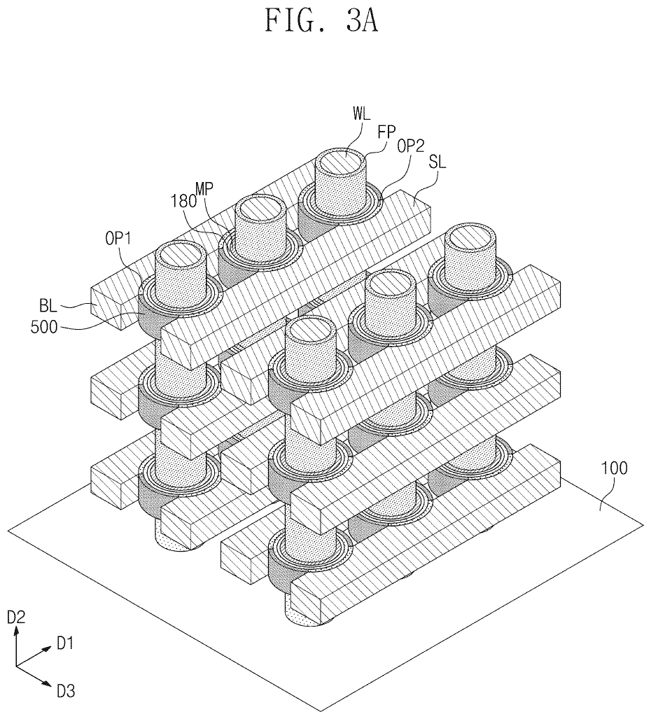

FIG. 3A is a schematic perspective view illustrating a semiconductor device according to an embodiment of the present inventive concept. FIG. 3B is a sectional view illustrating the semiconductor device of FIG. 3A.

Referring to FIGS. 3A and 3B, a stack SS may be disposed on the substrate 100. The stack SS may include the bit line BL, which are spaced apart from each other along the second direction D2, source lines SL, which are respectively spaced apart from the bit lines BL along the third direction D3, and the word lines WL, which are disposed between the bit line BL and the source line SL. The bit line BL may be extended along the first direction D1. The source line SL may be spaced apart from each other along the second direction D2 and may extend along the first direction D1.

As shown in FIGS. 3A and 3B, the bit line BL may extend along a direction parallel to the top surface of the substrate 100, which is the first direction D1 parallel to the top surface of the substrate 100. The word line WL may extend along a direction perpendicular to the top surface of the substrate 100, which is the second direction D2 perpendicular to the top surface of the substrate 100. The oxide semiconductor structure 500 may extend along a direction, which is parallel to the top surface of the substrate 100 and is perpendicular to the extension direction of the bit line BL, which is the third direction D3 parallel to the top surface of the substrate 100 and perpendicular to the first direction D1.

The word line WL may be provided and cross the bit line BL and the source line SL. The word lines WL may be provided between the bit line BL and the source line SL and may be spaced apart from each other in the first direction D1.

The bit line BL and the source line SL may be formed of or include at least one of conductive materials (e.g., doped polysilicon, metal, conductive metal nitride, conductive metal silicide, conductive metal oxide, or combinations thereof). The word line WL may be formed of or include at least one of doped polysilicon, Aluminum (Al), Copper (Cu), Titanium (Ti), Tantalum (Ta), Ruthenium (Ru), Tungsten (W), Molybdenum (Mo), Platinum (Pt), Nickel (Ni), Cobalt (Co), Titanium Nitride (TiN), Tantalum Nitride (TaN), Tungsten Nitride (WN), Niobium Nitride (NbN), Titanium Aluminum (TiAl), Titanium Aluminum Nitride (TiAIN), Titanium Silicon (TiSi), Titanium Silicon Nitride (TiSiN), Tantalum Silicon (TaSi), Tantalum Silicon Nitride (TaSiN), Ruthenium Titanium Nitride (RuTiN), Nickel Silicon (NiSi), Cobalt Silicon (CoSi), Iridium Oxide (IrOx), and Ruthenium Oxide (RuOx), or combinations thereof, but the present inventive concept is not necessarily limited to this example.

The stack SS may further include a plurality of oxide semiconductor structures 500, which may enclose a side surface WL_S of each of the word lines WL. The oxide semiconductor structure 500 may include the first oxide semiconductor pattern 200 and the second oxide semiconductor pattern 300. The first oxide semiconductor pattern 200 may be formed of or include indium oxide (In₂O₃). The second oxide semiconductor pattern 300 may be formed of or include gallium oxide (Ga₂O₃). The thickness of the first oxide semiconductor pattern 200 may be larger than the thickness of the second oxide semiconductor pattern 300. As an example, the thickness of the first oxide semiconductor pattern 200 may range from about 6 nm to 7.425 nm. The thickness of the second oxide semiconductor pattern 300 may range from about 1.275 nm to 1.9 nm. According to an embodiment of the present inventive concept, the thickness of the first oxide semiconductor pattern 200 may range from about 3 nm to 7 nm, and the thickness of the second oxide semiconductor pattern 300 may range from about 1 nm to 2 nm.

The oxide semiconductor structures 500 may enclose the side surface WL_S of a corresponding one of the word lines WL and may be spaced apart from each other along the first direction D1. The oxide semiconductor structures 500 may be disposed between the bit line BL and the source line SL. The bit line BL may be connected to each of the oxide semiconductor structures 500, and the source line SL may be connected to each of the oxide semiconductor structures 500. When viewed in a sectional view, the corresponding bit line BL, each of the oxide semiconductor structures 500, and the corresponding source line SL may overlap with each other horizontally (e.g., along the third direction D3).

The stack SS may further include a ferroelectric pattern FP between each of the oxide semiconductor structures 500 and the corresponding word line WL, a metal pattern MP between each of the oxide semiconductor structures 500 and the ferroelectric pattern FP, and the gate insulating pattern 180 between each of the oxide semiconductor structure 500 and the metal pattern MP. The ferroelectric pattern FP may enclose the side surface WL_S of the corresponding word line WL. The metal pattern MP may enclose the side surface WL_S of the corresponding word line WL and may be spaced apart from the side surface WL_S of the corresponding word line WL, with the ferroelectric pattern FP interposed therebetween.

Here, the first oxide semiconductor pattern 200 may be disposed closer to the gate insulating pattern 180 and the ferroelectric pattern FP than the second oxide semiconductor pattern 300. For example, the first oxide semiconductor pattern 200 may enclose the gate insulating pattern 180, and the first oxide semiconductor pattern 200 may be interposed between the gate insulating pattern 180 and the second oxide semiconductor pattern 300. The second oxide semiconductor pattern 300 may be spaced apart from the gate insulating pattern 180 by the first oxide semiconductor pattern 200.

The ferroelectric pattern FP may include hafnium oxide (HfO₂) with a ferroelectric property. The ferroelectric pattern FP may further include dopants, and in an embodiment of the present inventive concept, the dopants may be at least one of Zirconium (Zr), Silicon (Si), Aluminum (Al), Yttrium (Y), Gadolinium (Gd), Lanthanum (La), Scandium (Sc), and Strontium (Sr). The ferroelectric pattern FP may be formed of or include, for example, Hafnium Oxide (HfO₂), Hafnium Zinc Oxide (HfZnO), Hafnium Silicon Oxide (HfSiO), Hafnium Silicon Oxynitride (HfSiON), Hafnium Tantalum Oxide (HfTaO), Hafnium Titanium Oxide (HfTiO), and Hafnium Zirconium Oxide (HfZrO), or combinations thereof. The ferroelectric pattern FP may have an orthorhombic phase. The metal pattern MP may be formed of or include at least one of metallic materials (e.g., Platinum (Pt)) and/or metal oxide materials (e.g., Ruthenium (IV) oxide (RuO₂), Iridium (IV) oxide (IrO₂), and Lanthanum Strontium Cobaltite (LaSrCoO₃)). The metal pattern MP may maintain polarization of the ferroelectric pattern FP. A third gate insulating pattern 180c may be formed of or include at least one of silicon oxide (SiO₂), silicon oxynitride, high-k dielectric materials whose dielectric constants are higher than silicon oxide (SiO₂), or combinations thereof. The high-k dielectric materials may include metal oxide materials or metal oxynitride materials.

The stack SS may further include first impurity patterns OP1, which are provided between the bit line BL and the oxide semiconductor structures 500, and second impurity patterns OP2, which are provided between the source line SL and the oxide semiconductor structures 500. The first impurity patterns OP1 may be spaced apart from each other along the third direction D3 and may be respectively interposed between the bit line BL and the oxide semiconductor structures 500. The second impurity patterns OP2 may be spaced apart from each other along the third direction D3 and may be respectively interposed between the source line SL and the oxide semiconductor structures 500. The bit line BL may be electrically connected to the oxide semiconductor structures 500, respectively, through the first impurity patterns OP1, and the source line SL may be electrically connected to the oxide semiconductor structures 500, respectively, through the second impurity patterns OP2.

The first impurity patterns OP1 and the second impurity patterns OP2 may contain impurities of the same conductivity type. The first and second impurity patterns OP1 and OP2 may include n-type impurities or p-type impurities.

The word line WL, the oxide semiconductor structure 500 enclosing the side surface WL_S of the word line WL, the ferroelectric, metal, and gate insulating patterns FP, MP, and 180 interposed between the oxide semiconductor structure 500 and the word line WL, and the first and second impurity patterns OP1 and OP2 disposed at both sides of the oxide semiconductor structure 500 may constitute a ferroelectric field effect transistor.

The stack SS may further include fourth insulating patterns 106, which are interposed between the oxide semiconductor structures 500. The oxide semiconductor structures 500 may be electrically separated or disconnected from each other by the fourth insulating patterns 106.

Sidewall insulating patterns 131 may be disposed at both sides of the stack SS. One of the sidewall insulating patterns 131 may be provided to at least partially cover side surfaces of the bit line BL and the fourth insulating patterns 106 and may extend along the side surfaces of the bit line BL, which is along the first direction D1. Another one of the sidewall insulating patterns 131 may be provided to at least partially cover side surfaces of the source line SL and the fourth insulating patterns 106 and may extend along the side surfaces of the source line SL, which is along the first direction D1. In an embodiment of the present inventive concept, the sidewall insulating patterns 131 may be formed of or include at least one of silicon oxide (SiO₂), silicon nitride (Si₃N₄), and/or silicon oxynitride.

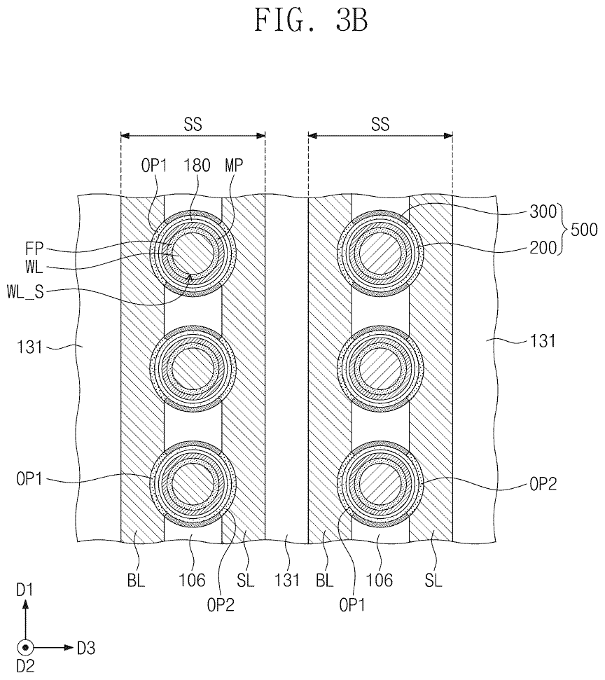

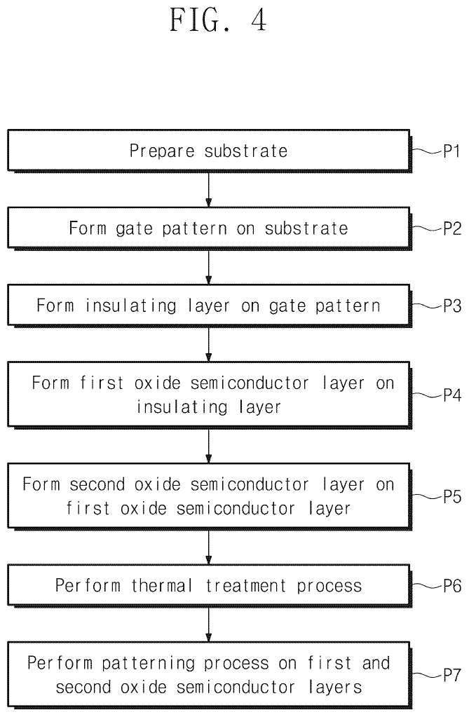

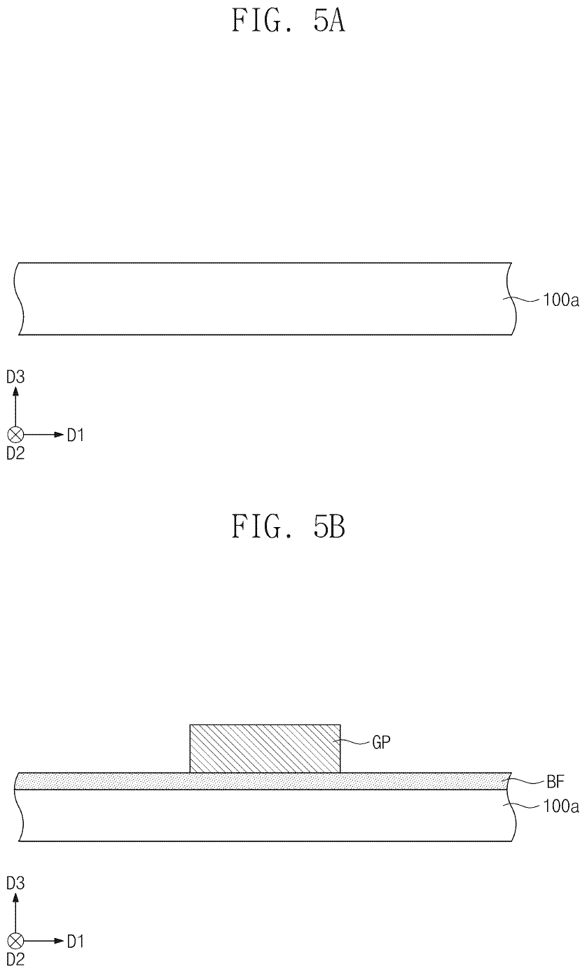

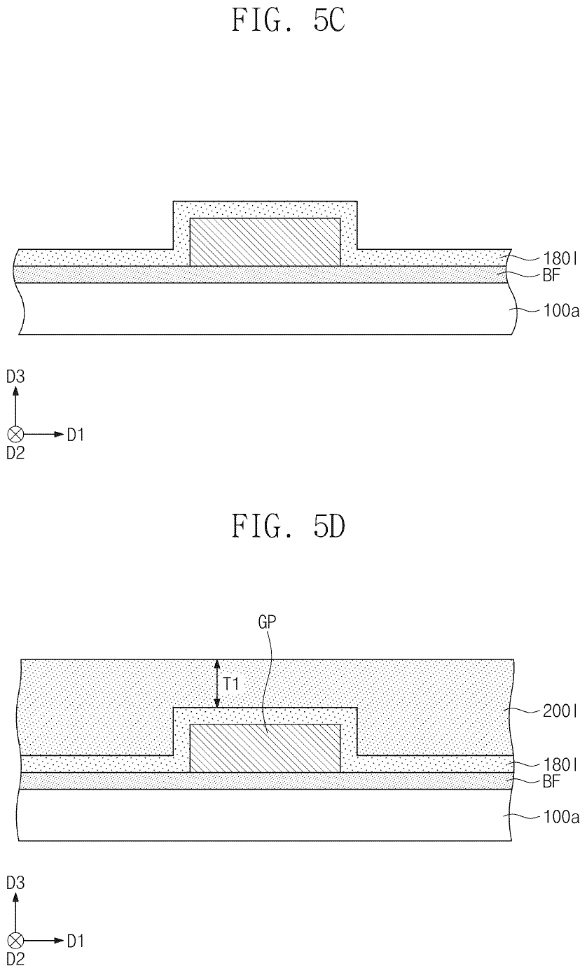

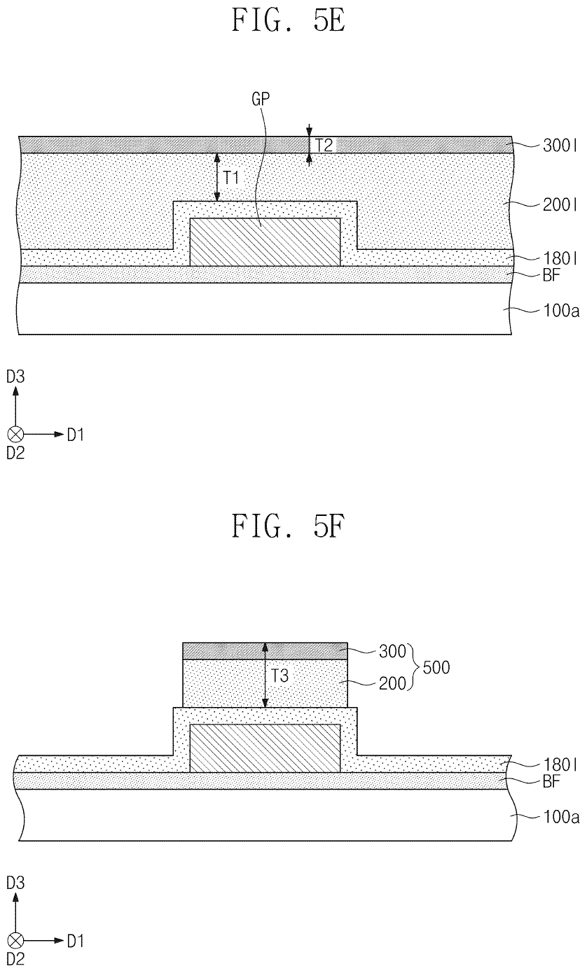

FIG. 4 is a process flow chart illustrating a method of forming an oxide semiconductor structure, according to an embodiment of the present inventive concept. FIGS. 5A to 5F are sectional views illustrating a process of fabricating a transistor including an oxide semiconductor structure, according to an embodiment of the present inventive concept.

Referring to FIGS. 4 and 5A, a first substrate 100a may be prepared (in P1). The first substrate 100a may be a semiconductor substrate (e.g., a silicon substrate). In an embodiment of the present inventive concept, the first substrate 100a may be a metal substrate, a plastic substrate, and a glass substrate.

Referring to FIGS. 4 and 5B, a buffer layer BF may be formed on the substrate 100. The buffer layer BF may be formed of or include at least one of inorganic or organic insulating materials and may have a single-or multi-layered structure.

A gate pattern GP may be formed on the buffer layer BF (in P2). The formation of the gate pattern GP may include forming a gate layer on the buffer layer BF and patterning the gate layer.

Referring to FIGS. 4 and 5C, an insulating layer 1801 may be formed on a top surface of the buffer layer BF and top and side surfaces of the gate pattern GP (in P3). The formation of the insulating layer 1801 may be formed by a chemical vapor deposition (CVD) process, a physical vapor deposition (PVD) process, or an atomic layer deposition (ALD) process.

Referring to FIGS. 4 and 5D, a first oxide semiconductor layer 2001 may be formed on the insulating layer 1801. The first oxide semiconductor layer 2001 may be formed of or include indium oxide (In₂O₃). The first oxide semiconductor layer 2001 may be formed by an atomic layer deposition (ALD) process.

For example, the formation of the first oxide semiconductor layer 2001 (in P4) may include performing a first unit process on the insulating layer 1801 repeatedly about 50 to 55 times. The first unit process may include providing a first precursor on the insulating layer 1801 and providing a first reaction source containing oxygen (O) and argon (Ar). The first unit process may be performed at a temperature of about 140° C. to 160° C.

The providing of the first precursor may include injecting the first precursor and performing a first purge step. The first precursor may include indium (In). In an embodiment of the present inventive concept, the first precursor may include trimethyl indium (In (CH₃)₃). The first precursor may be supplied for about 1 seconds to 2 seconds, and here, the gas flow rate of the first precursor may range from about 40 standard cubic centimeters per minute (sccm) to 60 sccm. The first purge step may be performed for about 4 seconds to 6 seconds.

The first reaction source may be provided, after the first purge step. The providing of the first reaction source may include providing a mixture gas of oxygen (O) and argon (Ar), providing plasma to the mixture gas of oxygen (O) and argon (Ar), and performing a second purge step. The oxygen (O) and argon (Ar) may be provided for about 5 seconds to 10 seconds, and here, the gas flow rates of the oxygen (O) and argon (Ar) may be from about 260 sccm to 280 sccm and from about 220 sccm to 230 sccm, respectively. An electric power, which is supplied to a plasma generator (not shown) to generate the plasma, may range from about 125 W to 175 W. The second purge step may be performed for about 5 seconds to 10 seconds.

According to an embodiment of the present inventive concept, in the case where the first unit process is performed once, a thickness of the first oxide semiconductor layer 2001 along the third direction D3 may range from about 0.12 nm to 0.135 nm.

Since the first unit process is repeated, the first oxide semiconductor layer 2001 may have a first thickness T1 along the third direction D3. Here, the first thickness T1 may be the smallest thickness of the first oxide semiconductor layer 2001 along the third direction D3. In the case where the first unit process is repeated about 50 to 55 times, the first thickness T1 may range from about 6 nm to 7.425 nm. In an embodiment of the present inventive concept, the first thickness T1 may range from about 3 nm to 7 nm, depending on the kind of the first precursor, the flow rate of the gas, the reaction time, and the process temperature.

Referring to FIGS. 4 and 5E, a second oxide semiconductor layer 3001 may be formed on the first oxide semiconductor layer 2001 (in P5). The second oxide semiconductor layer 3001 may be formed of or include gallium oxide (Ga₂O₃). The second oxide semiconductor layer 3001 may be formed by an atomic layer deposition (ALD) process.

For example, the formation of the second oxide semiconductor layer 3001 (in P5) may include repeating a second unit process on the first oxide semiconductor layer 2001 several times (e.g., about 15 to 20 times). The second unit process may include providing a second precursor on the first oxide semiconductor layer 2001 and providing a second reaction source containing oxygen (O) and argon (Ar). The second unit process may be performed at a temperature ranging from about 140° C. to 160° C.

The providing of the second precursor may include injecting the second precursor and performing a third purge step. The second precursor may include gallium (Ga). In an embodiment of the present inventive concept, the second precursor may include trimethyl gallium (Ga(CH₃)₃). The second precursor may be injected for about 1 seconds to 2 seconds, and here, a gas flow rate of the second precursor may range from about 40 sccm to 60 sccm. The third purge step may be performed for about 4 seconds to 6 seconds.

The second reaction source may be provided, after the third purge step. The providing of the second reaction source may include providing a mixture gas of oxygen (O) and argon (Ar), providing plasma to the mixture gas of oxygen (O) and argon (Ar), and performing a fourth purge step. The oxygen (O) and argon (Ar) may be provided for about 5 seconds to 10 seconds, and here, the gas flow rates of the oxygen (O) and argon (Ar) may be from about 260 sccm to 280 sccm and from about 220 sccm to 230 sccm, respectively. An electric power, which is supplied to the plasma generator to generate the plasma, may range from about 125 W to 175 W. The fourth purge step may be performed for about 5 seconds to 10 seconds.

According to an embodiment of the present inventive concept, in the case where the second unit process is performed once, a thickness of the second oxide semiconductor layer 3001 along the third direction D3 may range from about 0.085 nm to 0.095 nm. In the case where the second unit process is repeated, the second oxide semiconductor layer 3001 may have a second thickness T2 along the third direction D3. In the case where the second unit process is repeated about 15 to 20 times, the second thickness T2 may range from about 1.275 nm to 1.9 nm. In an embodiment of the present inventive concept, the second thickness T2 may range from about 1 nm to 2 nm, depending on the kind of the second precursor, the flow rate of the gas, the reaction time, and the process temperature.

Thereafter, a thermal treatment process may be performed on the first and second oxide semiconductor layers 2001 and 3001 (in P6). The thermal treatment process may be performed at a temperature ranging from about 350° C. to 450° C.

Referring to FIGS. 4 and 5F, a patterning process may be performed on the first and second oxide semiconductor layers 2001 and 3001. A length of each of the first and second oxide semiconductor layers 2001 and 3001 along the first direction D1 may be reduced by the patterning process, and thus, the first and second oxide semiconductor patterns 200 and 300 may be formed. As a result, the oxide semiconductor structure 500 including the first and second oxide semiconductor patterns 200 and 300 may be formed.

The oxide semiconductor structure 500 may have a third thickness T3 along the third direction D3. The third thickness T3 of the oxide semiconductor structure 500 may be substantially equal to a sum of the first and second thicknesses T1 and T2. In an embodiment of the present inventive concept, the third thickness T3 may range from about 7.275 nm to 9.325 nm.

The transistor, which includes the oxide semiconductor structure 500 according to an embodiment of the present inventive concept, may be fabricated by forming source and drain electrodes on the insulating layer 1801. The oxide semiconductor structure 500 may be used as a channel region of the transistor.

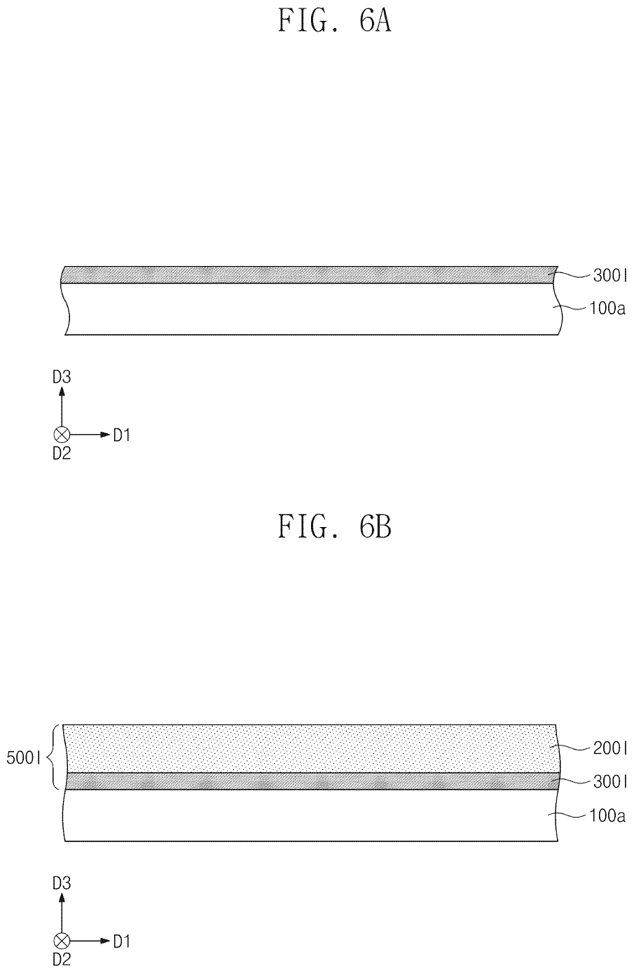

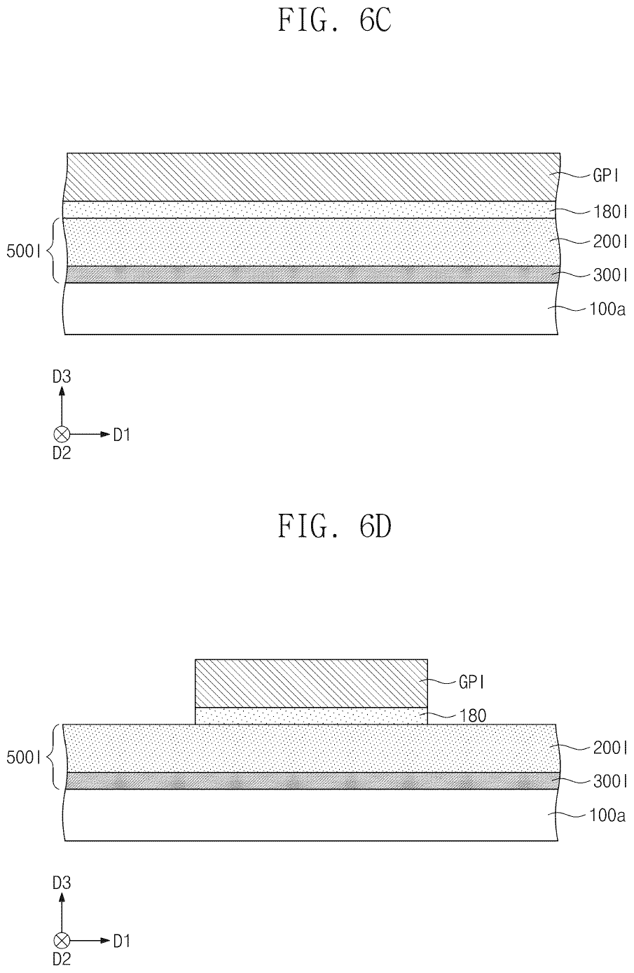

FIGS. 6A to 6D are sectional views illustrating a process of fabricating a transistor including an oxide semiconductor structure, according to an embodiment of the present inventive concept.

Referring to FIG. 6A, the second oxide semiconductor layer 3001 may be formed on the first substrate 100a. The formation of the second oxide semiconductor layer 3001 may be performed in a similar manner to the process described with reference to FIG. 5E.

For example, the formation of the second oxide semiconductor layer 3001 may include repeating the afore-described second unit process on the first substrate 100a several times (e.g., 15 to 20 times).

Referring to FIG. 6B, the first oxide semiconductor layer 2001 may be formed on the second oxide semiconductor layer 3001. The formation of the first oxide semiconductor layer 2001 may be performed in a similar manner to the process described with reference to FIG. 5D.

For example, the formation of the first oxide semiconductor layer 2001 may include repeating the afore-described first unit process on the second oxide semiconductor layer 3001 several times (e.g., 50 to 55 times).

Thereafter, a thermal treatment process may be performed on the first and second oxide semiconductor layers 2001 and 3001. The thermal treatment process may be performed at a temperature ranging from about 350° C. to 450° C. The oxide semiconductor structure 500 according to an embodiment of the present inventive concept may be formed, as a result of the thermal treatment process.

Referring to FIG. 6C, the insulating layer 1801 may be formed on the first oxide semiconductor layer 2001. For example, the first oxide semiconductor layer 2001 may be in contact with the insulating layer 1801, and the second oxide semiconductor layer 3001 may be spaced apart from the insulating layer 1801 by the first oxide semiconductor layer 2001.

Thereafter, a gate layer GP1 may be formed on the insulating layer 1801. The gate layer GPI may be deposited using a chemical vapor deposition process, a sputtering process, or an atomic layer deposition process.

Referring to FIG. 6D, a patterning process may be performed on the insulating layer 1801 and the gate layer GP1. A length of each of the insulating and gate layers 1801 and GP1 along the first direction D1 may be reduced by the patterning process, and as a result, the gate insulating pattern 180 and the gate pattern GP may be formed.

### First Embodiment

The oxide semiconductor structure 500 may be formed as described with reference to FIGS. 5A to 5E. For example, the first oxide semiconductor layer 2001 may be formed by successively performing the first unit process on the substrate 100 several times (e.g., 54 times). Thereafter, the second oxide semiconductor layer 3001 may be formed by successively performing the second unit process several times (e.g., 18 times).

### First Comparative Example

A first cycle, in which the successive repetition number of the first unit process in the first embodiment is changed to 3 and the repetition number of the second unit process in the first embodiment is changed to 1, may be performed. Thereafter, the first cycle may be repeated 18 times.

### Second Comparative Example

A second cycle, in which the successive repetition number of the first unit process in the first embodiment, is changed to 9 and the successive repetition number of the second unit process in the first embodiment is changed to 3, may be performed. Thereafter, the second cycle may be repeated 6 times.

### Third Comparative Example

A third cycle, in which the successive repetition number of the first unit process in the

first embodiment, is changed to 18 and the successive repetition number of the second unit process in the first embodiment is changed to 6, may be performed. Thereafter, the third cycle may be repeated 3 times.

### Fourth Comparative Example

A fourth cycle, in which the successive repetition number of the first unit process in the first embodiment, is changed to 27 and the successive repetition number of the second unit process in the first embodiment is changed to 9, may be performed. Thereafter, the fourth cycle may be repeated 2 times.

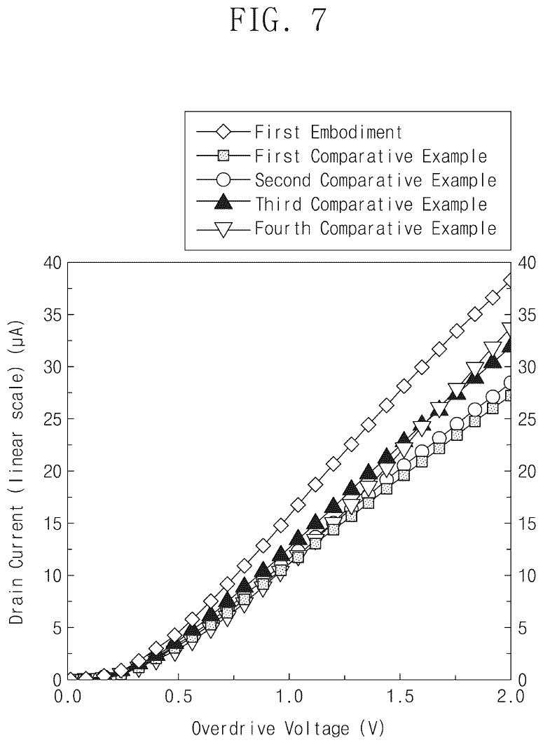

FIG. 7 is a graph showing a relationship between an overdrive voltage and a drain current, according to the first embodiment and the first to fourth comparative examples.

Referring to FIG. 7, the drain current by the overdrive voltage may be higher in the first embodiment than in the first to fourth comparative examples. In the present embodiment of the inventive concept, the overdrive voltage may mean a voltage that is obtained by subtracting a threshold voltage from a gate-source voltage.

In the case where the overdrive voltage was 1 V, the drain current in the first embodiment may be 15.8 μA. In some embodiments, the overdrive voltage may be 1 V in the drain current values in the first, second, third, and fourth comparative examples may be 11 μA, 11.6 μA, 12.6 μA, and 10.9 μA, respectively.

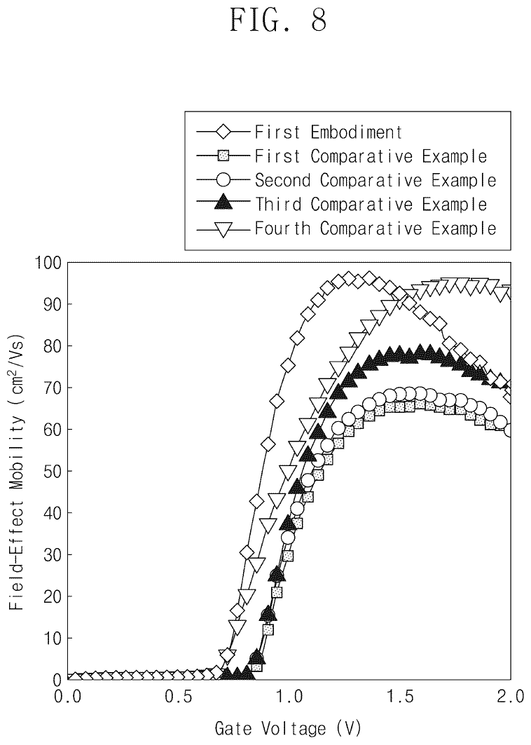

FIG. 8 is a graph showing a relationship between a gate electrode and a field-effect mobility, according to the first embodiment and the first to fourth comparative examples. The first embodiment and the first to fourth comparative examples may be the same as those in FIG. 7.

Referring to FIG. 8, the largest values of field-effect mobility by the gate voltage may be 91.6 cm²/(V·s), 63.1 cm²/(V·s), 65.4 cm²/(V·s), 74.3 cm²/(V·s) and 91.3 cm²/(V·s), respectively, in the first embodiment and the first to fourth comparative examples. Here, comparing gate voltages corresponding to the largest values of the field-effect mobility, the gate voltage in the first embodiment may be 1.2 V, which is smaller than those in the first to fourth comparative examples. For example, the electric characteristics in the first embodiment may be better than those in the first to fourth comparative examples in that the gate voltage for the largest value of the field-effect mobility was smaller than in the first embodiment than in the first to fourth comparative examples.

According to an embodiment of the present inventive concept, the oxide semiconductor structure may include a first oxide semiconductor pattern and a second oxide semiconductor pattern, and the first oxide semiconductor pattern may be in contact with a gate insulating pattern. Here, the first and second oxide semiconductor patterns may include indium oxide (In₂O₃) and gallium oxide (Ga₂O₃), respectively. Due to the indium oxide (In₂O₃), the conductivity of the oxide semiconductor structure may increase, and due to the gallium oxide (Ga₂O₃), the randomness of the crystal structure of the indium oxide (In₂O₃) may be controlled.

In addition, a two-dimensional electron gas may be produced near a boundary between oxide semiconductor patterns including materials with different band gaps, and in this case, a charge density may be increased near the boundary between the corresponding patterns. As the charge density increases, the field-effect mobility of the oxide semiconductor structure may increase.

An oxide semiconductor structure according to an embodiment of the present inventive concept may include a first oxide semiconductor pattern and a second oxide semiconductor pattern. The first and second oxide semiconductor patterns may include indium oxide (In₂O₃) and gallium oxide (Ga₂O₃), respectively. Here, the first oxide semiconductor pattern including the indium oxide (In₂O₃) may be in contact with a gate insulating pattern. Due to the indium oxide (In₂O₃), the conductivity of the oxide semiconductor structure may increase, and due to the gallium oxide (Ga₂O₃), the randomness of the crystal structure of the indium oxide (In₂O₃) may be controlled.

While example embodiments of the inventive concept have been particularly shown and described, it will be understood by one of ordinary skill in the art that variations in form and detail may be made therein without departing from the spirit and scope of the present disclosure.

What is claimed is:

1. A semiconductor device, comprising:
a substrate;
a bit line disposed on the substrate and extending along a first direction;
a word line extending along a second direction perpendicular to the first direction;
an oxide semiconductor structure disposed on a surface of the word line and extending along a third direction perpendicular to the first and second directions; and
a gate insulating pattern disposed between the word line and the oxide semiconductor structure,
wherein two of the first, second, and third directions are parallel to a top surface of the substrate, and the other is perpendicular to the top surface of the substrate,
wherein the oxide semiconductor structure comprises:
a first oxide semiconductor pattern adjacent to the gate insulating pattern; and
a second oxide semiconductor pattern spaced apart from the gate insulating pattern, with the first oxide semiconductor pattern interposed therebetween,
wherein the first oxide semiconductor pattern comprises indium oxide,
wherein the second oxide semiconductor pattern comprises gallium oxide, and
wherein a thickness of the first oxide semiconductor pattern is larger than a thickness of the second oxide semiconductor pattern.

2. The semiconductor device of claim 1, wherein a content of indium (In) in the oxide semiconductor structure ranges from about 75 wt % to about 85 wt %.

3. The semiconductor device of claim 1, wherein a content of gallium (Ga) in the oxide semiconductor structure ranges from about 15 wt % to about 25 wt %.

4. The semiconductor device of claim 1, wherein the oxide semiconductor structure comprises a first vertical portion and a second vertical portion, which are spaced apart from each other along the first direction and face each other,
wherein the first and second vertical portions extend along the third direction, and
wherein a plurality of the word lines are disposed on inner side surfaces of the first and second vertical portions.

5. The semiconductor device of claim 4, wherein the first direction is parallel to the top surface of the substrate,
wherein the second direction is parallel to the top surface of the substrate and is perpendicular to the first direction, and
wherein the third direction is perpendicular to the top surface of the substrate.

6. The semiconductor device of claim 1, wherein a surface of the oxide semiconductor structure is in contact with the bit line.

7. The semiconductor device of claim 1, wherein the first oxide semiconductor pattern is in contact with the gate insulating pattern, and
wherein the semiconductor device further comprises a landing pad disposed on the oxide semiconductor structure and a capacitor disposed on the landing pad.

8. The semiconductor device of claim 1, wherein a side surface of the oxide semiconductor structure is connected to the bit line,
wherein the semiconductor device further comprises a capacitor connected to an opposite side surface of the oxide semiconductor structure, and
wherein the capacitor extends along the third direction.

9. The semiconductor device of claim 8, wherein the first direction is perpendicular to the top surface of the substrate,
wherein the second direction is parallel to the top surface of the substrate, and
wherein the third direction is parallel to the top surface of the substrate and is perpendicular to the second direction.

10. The semiconductor device of claim 1, further comprising a ferroelectric pattern disposed between the word line and the oxide semiconductor structure.

11. The semiconductor device of claim 10, wherein the first direction is parallel to the top surface of the substrate,
wherein the second direction is perpendicular to the top surface of the substrate, and
wherein the third direction is parallel to the top surface of the substrate and is perpendicular to the first direction.

12. The semiconductor device of claim 10, further comprising a metal pattern disposed between the oxide semiconductor structure and the ferroelectric pattern,
wherein the first oxide semiconductor pattern is closer to the ferroelectric pattern than the second oxide semiconductor pattern.

13. The semiconductor device of claim 12, wherein the gate insulating pattern is disposed between the first oxide semiconductor pattern and the metal pattern, and
wherein the ferroelectric pattern encloses a side surface of the word line.

14. The semiconductor device of claim 10, further comprising an impurity pattern disposed between the bit line and the oxide semiconductor pattern,
wherein the first oxide semiconductor pattern encloses the gate insulating pattern.

15. A semiconductor device, comprising:
a substrate;
a bit line disposed on the substrate and extending along a first direction;
a word line extending along a second direction perpendicular to the first direction;
a channel structure disposed on a surface of the word line and extending along a third direction perpendicular to the first and second directions; and
a gate insulating pattern disposed between the word line and the channel structure,
wherein two of the first, second, and third directions are parallel to the top surface of the substrate, and the remaining direction is perpendicular to the top surface of the substrate,
wherein the channel structure comprises:
a first oxide semiconductor pattern in contact with the gate insulating pattern; and
a second oxide semiconductor pattern spaced apart from the gate insulating pattern, with the first oxide semiconductor pattern interposed therebetween,
wherein the first oxide semiconductor pattern comprises indium oxide,
wherein the second oxide semiconductor pattern comprises gallium oxide, and
wherein molar compositions of indium cations and gallium cations in the channel structure range from about 65% to about 75% and from about 25% to about 35%, respectively.

16. The semiconductor device of claim 14, wherein the first oxide semiconductor pattern is in contact with the gate insulating pattern, and wherein the second oxide semiconductor pattern is in contact with the bit line.

17. The semiconductor device of claim 15, wherein a content of indium (In) in the channel structure ranges from about 75 wt % to about 85 wt %, and
wherein a content of gallium (Ga) in the channel structure ranges from about 15 wt % to about 25 wt %.

18. A semiconductor device, comprising:
a substrate;
a plurality of bit lines disposed on the substrate and extended in a first direction;
a plurality of word lines extending along a second direction perpendicular to the first direction;
oxide semiconductor structures disposed on a surface of the word line and extending along a third direction perpendicular to the first and second directions; and
a gate insulating pattern disposed between the word line and each of the oxide semiconductor structures,
wherein two of the first, second, and third directions are parallel to a top surface of the substrate, and the remaining direction is perpendicular to the top surface of the substrate,
wherein each of the oxide semiconductor structures comprises:
a first oxide semiconductor pattern in contact with the gate insulating pattern; and
a second oxide semiconductor pattern spaced apart from the gate insulating pattern, with the first oxide semiconductor pattern interposed therebetween,
wherein the first oxide semiconductor pattern comprises indium oxide,
wherein the second oxide semiconductor pattern comprises gallium oxide,
wherein a thickness of the first oxide semiconductor pattern ranges from about 6 nm to about 7.425 nm, and
wherein a thickness of the second oxide semiconductor pattern ranges from about 1.275 nm to about 1.9 nm.

19. The semiconductor device of claim 18, wherein the oxide semiconductor structure includes one first oxide semiconductor pattern and one second oxide semiconductor pattern.

20. The semiconductor device of claim 18, further comprising a landing pad disposed on the oxide semiconductor structure and a capacitor disposed on the landing pad.
